(19) United States
(12) Patent Application Publication
(10) Pub. No.: US 2007/0087480 A1
(43) Pub. Date: Apr. 19, 2007

(54) CHIP PACKAGE METHOD

(75) Inventors: Su TAO, Kaohsiung (TW); Kuang-Lin Lo, Kaoshiung Hsien (TW); Tsung-Sheng Lee, Kaohsiung (TW); Yaw-Yuh Yang, Tainan (TW); Yuan-Kai Tao, Kaohsiung Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ADVANCED SEMICONDUCTOR ENGINEERING, INC., Kaohsiung (TW)

(21) Appl. No.: 11/613,195

(22) Filed: Dec. 20, 2006

Related U.S. Application Data
(62) Division of application No. 10/605,034, filed on Sep. 3, 2003.

(30) Foreign Application Priority Data
Dec. 31, 2002 (TW) 91137974

(51) Int. Cl. H01L 21/78

(52) U.S. Cl. 438/112; 438/460

(57) ABSTRACT

The present invention relates to a method for manufacturing a semiconductor chip package structure including the following steps. A substrate is provided. A plurality of chips are assembled onto the substrate and are electrically connected with the substrate. A stiffener is assembled onto the substrate and the stiffener has a top surface and a bottom surface facing the substrate. A molding compound is formed to cover the semiconductor chip, the substrate, the top surface and the bottom surface of the stiffener. Afterwards, a singulation step is performed to cut the molding compound, the substrate and the stiffener.

### CROSS-REFERENCE TO RELATED APPLICATION

This is a divisional application of application Ser. No. 10/605,034, filed Sep. 3, 2003, which claims the priority benefit of Taiwan application serial no. 91137974, filed on Dec. 31, 2002. The entirety of each of the above-mentioned patent applications is hereby incorporated by reference herein and made a part of this specification.

### BACKGROUND OF THE INVENTION

1. Field of Invention

The present invention relates to a chip package structure and a method for manufacturing the chip package structure. More particularly, the present invention relates to a chip package structure with less warpage and a method for manufacturing the chip package structure.

2. Description of Related Art

In the semiconductor industry, integrated circuits (ICs) manufacture can be categorized as three stages: fabrication of the dies, fabrication of the ICs and packaging of the ICs. Through wafer preparation, circuitry design, mask fabrication and wafer dicing, the bare dies are obtained. Each die has bonding pads for outwardly electrical connections. Encapsulation of the die using the molding materials is carried, so that the die is protected from the influences of moisture, heat and noises.

The design of the electrical products becomes more complex, smaller-sized and humanized, in order to offer more convenience for the consumers. In semiconductor packaging, quite a few small-scale chip package structures are developed, including chip scale package (CSP), mini ball-grid-array (mini BGA) and micro ball-grid-array (micro BGA). Taking the mini BGA as an example, the backs of the chips are attached to the substrate and the chips are electrically connected to the substrate through wire bonding. The chips and the substrate are simultaneously encapsulated by injecting the encapsulating material. After performing sigulation by using dicing, a plurality of chip package structures are obtained. In the mini BGA packaging, the sum of areas of the chip package structures is equivalent to the total area of the substrate. Therefore, the packaging integration can be increased and the production can be raised. Since the manufacturing cost is low and the production is high, mini BGA packaging is widely applied in the semiconductor packaging processes.

FIGS. 1A and 1B illustrate the prior art mini BGA package structure. FIG. 1 A is a top view of the prior art mini B GA package before dicing, while FIG. 1B is a cross-sectional view of the prior art mini BGA package after dicing. Referring to FIGS. 1A and 1B, in the prior art mini BGA package, a plurality of chips 130 are arranged in arrays onto a substrate 110, and are electrically connected to the substrate 110 through wires 180. Encapsulation is then performed by placing a mold (not shown) onto the substrate 110 covering the chips 130 (chips 130 disposed within the cavity of the mold) and injecting a molding compound 170 into the cavity of the mold. The chips 130 and wires 182 are covered by the molding compound 170. Afterwards, dicing is performed to form a plurality of chip package structures 102. Each chip package structure 102 includes the substrate 110, the chip 130 and the molding compound 170.

However, because of the stress in the dicing process, the chip package structure 102 often suffers warpage, especially when the substrate 110 is rather thin, as shown in FIG. 1B. If the chip package structure 102 is arranged to a mother board (not shown), the distance from the edge of the warped chip package structure 102 to the board is larger than the distance from the middle portion of the warped chip package structure 102 to the board. Due to warpage of the chip package structure 102, the solder balls on the edge of the chip package structure are often broken and peeled from the attached board through repetitious thermal cycles.

### SUMMARY OF THE INVENTION

The present invention provides a chip package structure with less warpage and a method for manufacturing the chip package structure.

The present invention provides a chip package structure and a method for manufacturing the chip package structure, which increases reliability of the attachment between the substrate and the mother board.

As embodied and broadly described herein, the present invention provides a method for manufacturing a semiconductor chip package structure including the following steps. A substrate is provided. A plurality of chips are assembled onto the substrate and are electrically connected with the substrate. A stiffener is assembled onto the substrate and the stiffener has a top surface and a bottom surface facing the substrate. A molding compound is formed to cover the semiconductor chip, the substrate, the top surface and the bottom surface of the stiffener. Afterwards, a singulation step is performed to cut the molding compound, the substrate and the stiffener.

According to one embodiment, the stiffener includes a plurality of openings and the locations of the openings correspond to the locations of the chips disposed on the substrate. The inner surface of the stiffener faces the substrate. After performing the sigulation step for cutting the stiffener, the chips and the substrate, the solder balls are formed on the substrate. Alternatively, the solder balls are formed before the sigulation step. Moreover, the chips are attached to the substrate via an adhesive and a plurality of wires are formed by wire-bonding to electrically connect the chips and the substrate.

Because the stiffener provides rigidity, warpage of the chip package structure is greatly reduced during the dicing process, even with the substrate as thin as about 0.1-0.5 mm. Through the support of the stiffener, the chip package structure of the present invention is flat. Therefore, the solder balls on the substrate of the chip package structure are firmly attached to the board, without peeling or breakage, even through repetitious thermal cycles. The reliability for the attachment between the substrate and the board is increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of the prior art mini BGA package before dicing.

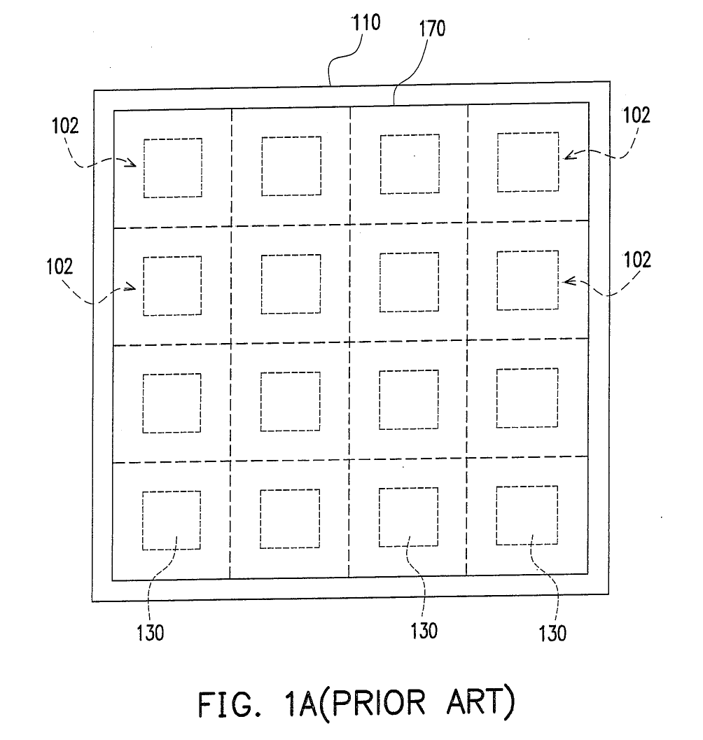

FIG. 1B is a cross-sectional view of the prior art mini BGA package after dicing.

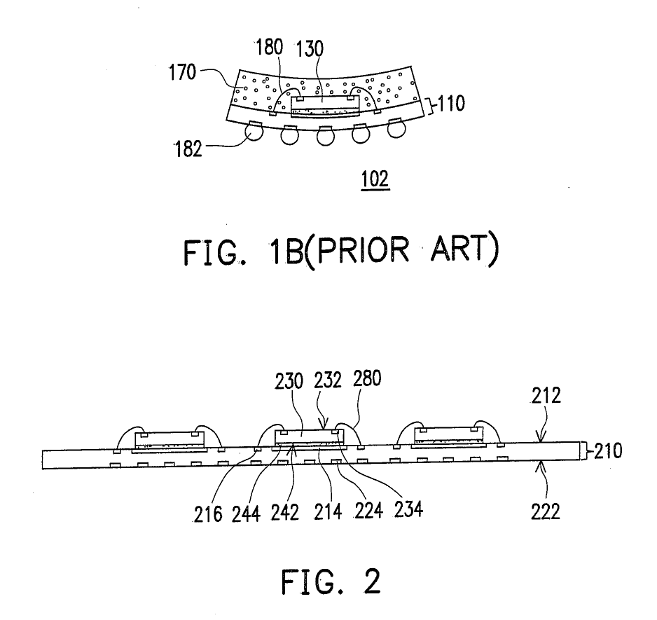

FIGS. 2-8 are cross-sectional views illustrating the manufacturing steps of the mini BGA package structure according to one preferred embodiment of the present invention.

FIG. 3A is a top view showing the BGA package structure in FIG. 3 according to one preferred embodiment of the present invention.

FIG. 9 is a cross-sectional view illustrating another mini BGA package structure according to one preferred embodiment of the present invention.

FIGS. 10-11 are cross-sectional views illustrating the mini BGA package structure according to another preferred embodiment of the present invention.

### DESCRIPTION OF THE PREFERRED EMBODIMENTS

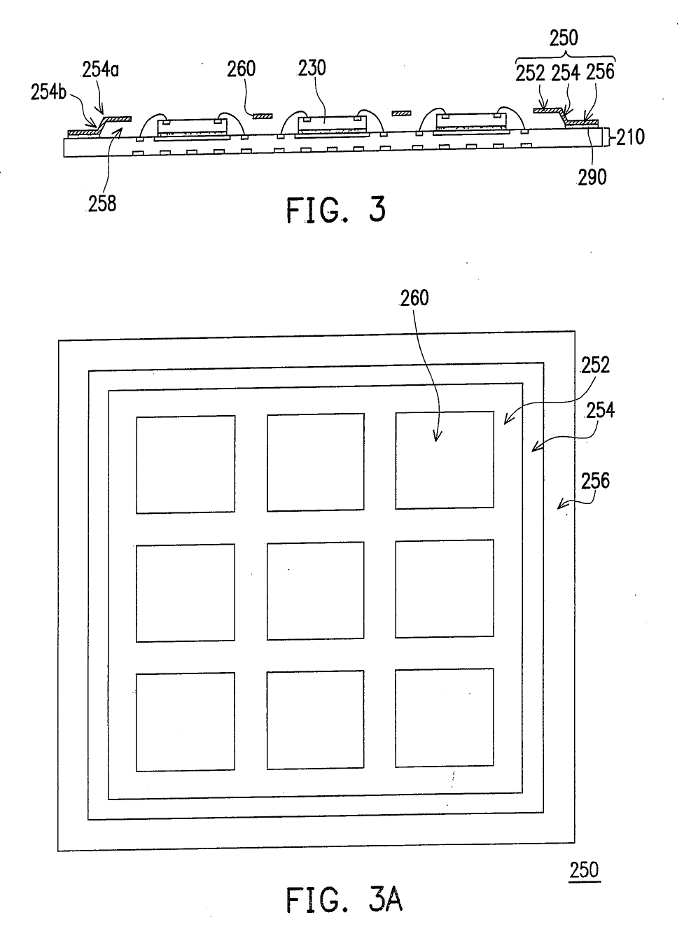

FIGS. 2-8 are cross-sectional views illustrating the manufacturing steps of the mini BGA package structure according to one preferred embodiment of the present invention.

Referring to FIG. 2, a substrate 210 is provided with a top surface 212 and a bottom surface 222. The substrate 210 includes a plurality of die pads 214, contacts 216, 224. The die pads 214 are arranged in arrays on the top surface 212 of the substrate 210. Contacts 216 are arranged around the corresponding die pad 214 on the top surface 212 of the substrate 210, while contacts 224 are disposed on the bottom surface 222 of the substrate 210.

A plurality of chips 230 are provided, and each chip 230 has an active surface 232 and an opposite back surface 242. Each chip 230 includes a plurality of contacts 234, surrounding the periphery of the active surface 232 and disposed on the active surface 232. The back surface 242 of each chip 230 is attached to the corresponding die pad 214 of the substrate 210 through an adhesive 244. Each chip 230 is electrically connected to the substrate 210 through wires 280 by wire bonding. One end of the wire 280 is attached to the contact 234 of the chip 230, while the other end of the wire 280 is connected to the contact 216 of the substrate 210.

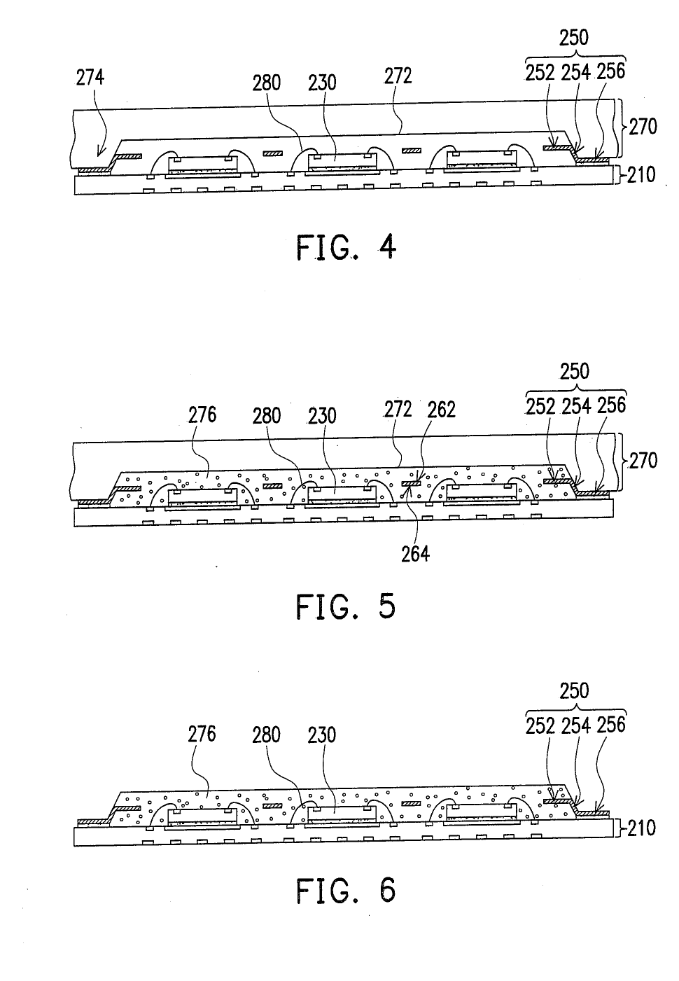

FIG. 3A is a top view showing the structure in FIG. 3. Referring to FIGS. 3 and 3A, an adhesive 290 is applied to attach a stiffener 250 to the substrate 210. The stiffener 250 is a cap structure including a top (roof) portion 252, sidewalls 254 and a flange portion 256. The top portion 252 is supported and surrounded by the surrounding sidewalls 254. An upper portion 254a of the sidewall 252 is connected to the periphery of the top portion 252. The sidewalls 254 are declivous walls, not perpendicular to the top portion 252. A space 258, formed between the slopy sidewalls 254 and the top portion, can accommodate a plurality of chips 230. The stiffener 250 includes a plurality of openings 260, arranged in arrays on the top portion 252 of the stiffener 250. The locations of the openings 260 correspond to the locations of chips 230 on the substrate 210. The flange portion 256 is connected to a lower portion 254b of the sidewalls 254. The flange portion 256 encircles the lower portion 254b of the sidewalls 254 and extends outwardly from the sidewalls 254. The stiffener 250 is fixed to the substrate 210 via the flange portion 256. The material of the stiffener 250 is copper or other non-flexible materials, for example.

Referring to FIG. 4, a mold 270 with a cavity 272 and a sidling portion 274 round the cavity 272. As the mold 270 is placed onto the substrate 210, the sidling portion 274 of the mold 270 is pressed onto the flange portion 256 of the stiffener 250. The chips 230, wires 280 and the stiffener 250 reside within the cavity 272 of the mold 270. Later on, a molding compound 276 is injected into the cavity 272 of the mold 270, as shown in FIG. 5, covering the chips 230, wires 280 and the stiffener 250. An outer surface 262 and an inner surface 264 of the stiffener 250 are covered by the molding compound 276. The inner surface 264 of the stiffener faces the substrate 210. After the cooling and the de-molding (mold removing) steps, the structure as shown in FIG. 6 is obtained.

Later on, a singulation (dicing) process is performed to divide the molding compound 276, the stiffener 250 and the substrate 210 to obtain a plurality of individual chip package structures 300, as shown in FIG. 7. Each chip package structure 300 includes a portion of the substrate 210, the chip 230, a plurality of wires 280, a part of the top portion 256 of the stiffener 250 and molding compound 276, arranged as described above and shown in FIG. 7. A plurality of solder balls 282 are formed on the contacts 224 of the substrate 210 by solder-ball attachment, as shown in FIG. 8.

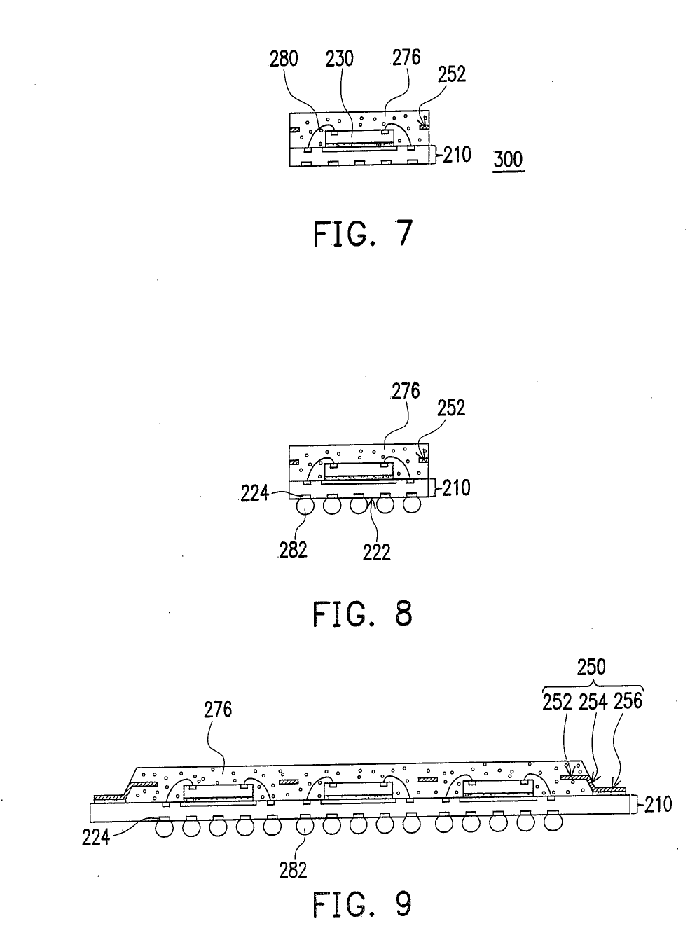

In the above embodiment, the dicing process is performed prior to the formation of solder balls. Alternatively, it is possible to form solder balls before the sigulation process. FIG. 9 is a cross-sectional view illustrating another mini BGA package structure according to one preferred embodiment of the present invention. As shown in FIG. 9, after the encapsulation, a plurality of solder balls 282 are attached to the contacts 224 of the substrate 210. The dicing process is then performed to cut the molding compound 276, the stiffener 250 and the substrate 210 to form a plurality of individual chip package structures 300, as shown in FIG. 8.

Referring to FIG. 8, because the stiffener 250 within the chip package structure 300 is quite rigid, warpage of the chip package structure 300 is greatly reduced during the dicing process, even with the substrate 210 as thin as about 0.1-0.5 mm. Through the support of the stiffener 250, the bottom surface 222 of the substrate 210 is straight and flat. When the chip package structure 300 is arranged to the mother board (not shown), the difference between the distance from the edge of the chip package structure 300 to the board and the distance from the middle portion of the chip package structure 300 to the board is greatly reduced. Therefore, the solder balls 282 on the edge of the substrate 210 in the chip package structure 300 are firmly attached to the board, without peeling or breakage, even through repetitious thermal cycles. As a result, the reliability for the attachment between the substrate and the board is increased.

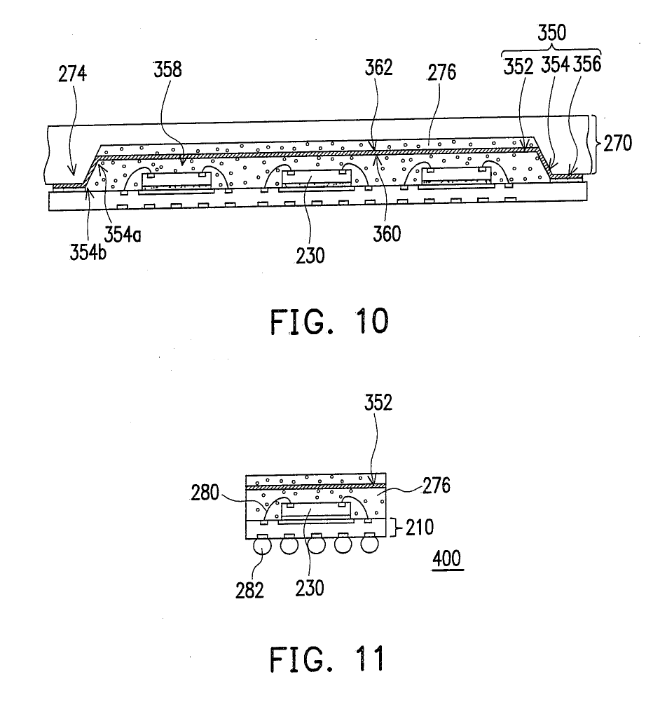

As described in the above embodiment, the stiffener includes a plurality of openings, arranged in arrays on the top portion of the stiffener. However, the stiffener without openings is also applicable and included within the scope of the present invention. FIGS. 10-11 are cross-sectional views illustrating the mini BGA package structure according to another preferred embodiment of the present invention. The same reference numbers used in the previous figures represent the same objects without further explanation.

As shown in FIG. 10, the stiffener 350 is a cap structure including a top (roof) portion 352, sidewalls 354 and a flange portion 356. The top portion 352 is supported and surrounded by the surrounding sidewalls 354. An upper portion 354a of the sidewall 352 is connected to the periphery of the top portion 352. The sidewalls 354 are declivous walls, not perpendicular to the top portion 352. A space 358, formed between the slopy sidewalls 354 and the top portion, can accommodate a plurality of chips 230. The flange portion 356 is connected to a lower portion 354b of the sidewalls 354. The flange portion 356 encircles the lower portion 354b of the sidewalls 354 and extends outwardly from the sidewalls 354. The stiffener 350 is fixed to the substrate 210 via the flange portion 356. During the encapsulation process, the sidling portion 274 of the mold 270 is pressed to the flange portion 356 of the stiffener 350. The molding compound 276 covers the inner surface 360 and the outer surface 362 of the stiffener 350. The material of the stiffener 350 is copper or other non-flexible materials, for example.

Referring to FIG. 11, after the encapsulation process, the formation of solder balls and the siglation process are performed as described above. A plurality of individual chip package structures 400 are obtained. Each chip package structure 400 includes a portion of the substrate 210, the chip 230, a plurality of wires 280, a part of the top portion 356 of the stiffener 350, molding compound 276 and solder balls 282, arranged as described above.

In conclusion, the present invention has at least the following advantages: 1. Because the stiffener provides rigidity, warpage of the chip package structure is greatly reduced during the dicing process, even with the substrate 210 as thin as about 0.1-0.5 mm. 2. Through the support of the stiffener, the chip package structure of the present invention is flat. Therefore, the solder balls on the substrate of the chip package structure are firmly attached to the board, without peeling or breakage, even through repetitious thermal cycles. 3. The reliability for the attachment between the substrate and the board is increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following clains and their equivalents.

What is claimed is:

1. A chip package structure process, comprising:
providing a matrix substrate;
disposing a plurality of chips on the matrix substrate and the chips are electrically connected to the matrix substrate;
disposing a stiffener on the matrix substrate, wherein the stiffener includes an outer surface and an opposite inner surface and the inner surface of the stiffener faces the matrix substrate, and wherein the stiffener has a top portion, sidewalls and a flange portion, and has a plurality of openings on the top portion, and the chips are completely exposed by the openings of the stiffener, wherein the top portion of the stiffener is flat;
providing a molding compound to cover the chips, the matrix substrate, the outer surface and the inner surface of the stiffener; and
dicing the molding compound, the matrix substrate and the stiffener to form a plurality of chip package structures.

2. The chip package structure process of claim 1, wherein the stiffener is attached to the matrix substrate through an adhesive.

3. The chip package structure process of claim 1, wherein a plurality of solder balls are formed on the matrix substrate after dicing the molding compound, the matrix substrate and the stiffener.

4. The chip package structure process of claim 1, wherein a plurality of solder balls are formed on the matrix substrate before dicing the molding compound, the matrix substrate and the stiffener.

5. The chip package structure process of claim 1, wherein the chips are attached to the matrix substrate tlirough an adhesive in the step of disposing the plurality of chips and a plurality of wires are formed by wire-bonding to electrically connect the chips and the matrix substrate.

6. The chip package structure process of claim 1, wherein a material of the stiffener is copper.
